(19) United States
(12) Patent Application Publication
(10) Pub. No.: US 2025/0311515 A1
(43) Pub. Date: Oct. 2, 2025

(54) METHOD FOR MANUFACTURING LIGHT-EMITTING DEVICE, AND LIGHT-EMITTING DEVICE

(71) Applicant: NICHIA CORPORATION, Anan-shi (JP)

(72) Inventor: Shinya KONDO, Tokushima-shi (JP)

(73) Assignee: NICHIA CORPORATION, Anan-shi (JP)

(21) Appl. No.: 19/083,001

(22) Filed: Mar. 18, 2025

(30) Foreign Application Priority Data
Mar. 28, 2024 (JP) 2024-054080

(51) Int. Cl. H10H 29/856; H10H 29/01; H10H 29/03; H10H 29/24

(52) U.S. Cl. CPC H10H 29/856; H10H 29/03; H10H 29/0363; H10H 29/24

(57) ABSTRACT

A method for manufacturing a light-emitting device includes: providing a first structure including: a substrate having a first surface and a second surface, a plurality of semiconductor light-emitting units disposed on the second surface, and a semiconductor portion disposed on the second surface in a region in which the plurality of semiconductor light-emitting units are not disposed, the semiconductor portion being configured to emit no light; disposing the first structure on a support member such that the second surface faces the support member, disposing a first resin member between a portion of the first structure and a portion of the support member; and after the disposing of the first resin member, separating the substrate from the plurality of semiconductor light-emitting units and the semiconductor portion by irradiating laser light from a first surface side of the substrate toward the plurality of semiconductor light-emitting units and the semiconductor portion.

### CROSS-REFERENCE TO RELATED APPLICATION

This application claims priority to Japanese Patent Application No. 2024-054080, filed on Mar. 28, 2024, the disclosure of which is hereby incorporated by reference in its entirety.

### TECHNICAL FIELD

The present disclosure relates to a method for manufacturing a light-emitting device and to a light-emitting device.

### BACKGROUND

In a method for manufacturing a light-emitting element, a sapphire substrate provided with a light-emitting element is, for example, detached by laser lift-off, as disclosed in Japanese Patent Publication No. 2021-163945.

### SUMMARY

An object of the present disclosure is to provide a method for manufacturing a light-emitting device and a light-emitting device in which light absorption is reduced.

According to one aspect of the present disclosure, a method for manufacturing a light-emitting device includes providing a first structure including a substrate having a first surface and a second surface located opposite to the first surface, a plurality of semiconductor light-emitting units disposed on the second surface of the substrate, and a semiconductor portion disposed in a region of the second surface in which the plurality of semiconductor light-emitting units are not disposed, the semiconductor portion emitting no light; disposing the first structure on a support member with the second surface facing the support member; disposing a first resin member between the first structure and the support member; and separating the substrate from the plurality of semiconductor light-emitting units and the semiconductor portion by emitting laser light from a side of the first surface of the substrate toward the plurality of semiconductor light-emitting units and the semiconductor portion after the disposing of the first resin member.

According to another aspect of the present disclosure, a light-emitting device includes a plurality of semiconductor light-emitting units each having a light-emitting surface; a first resin member having a first resin surface and disposed between the plurality of semiconductor light-emitting units such that the light-emitting surface is exposed on the first resin surface; and a semiconductor portion having a lower surface and an upper surface, the lower surface being covered by the first resin member, the upper surface being exposed on the first resin surface, and the semiconductor portion emitting no light, in which a light reflectance of the first resin member in contact with the lower surface of the semiconductor portion is higher than a light reflectance of the first resin surface.

According to the present disclosure, it is possible to provide a method for manufacturing a light-emitting device and a light-emitting device in which light absorption is reduced.

### BRIEF DESCRIPTION OF DRAWINGS

FIG. 1 is a schematic plan view of a light-emitting device according to an embodiment.

FIG. 2 is a schematic cross-sectional view taken along line II-II in FIG. 1.

FIG. 3 is an enlarged cross-sectional view of a portion of the light-emitting device according to the embodiment.

FIG. 4 is an enlarged cross-sectional view of a portion of the light-emitting device according to the embodiment.

FIG. 5 is a schematic plan view for illustrating a step of a method for manufacturing the light-emitting device according to the embodiment.

FIG. 6 is a schematic plan view for illustrating a step of the method for manufacturing the light-emitting device according to the embodiment.

FIG. 7 is a schematic cross-sectional view taken along line VII-VII of FIG. 6.

FIG. 8 is a schematic cross-sectional view for illustrating a step of the method for manufacturing the light-emitting device according to the embodiment.

FIG. 9 is a schematic cross-sectional view for illustrating a step of the method for manufacturing the light-emitting device according to the embodiment.

FIG. 10 is a schematic cross-sectional view for illustrating a step of the method for manufacturing the light-emitting device according to the embodiment.

FIG. 11 is a schematic cross-sectional view for illustrating a step of the method for manufacturing the light-emitting device according to the embodiment.

FIG. 12 is a schematic cross-sectional view for illustrating a step of the method for manufacturing the light-emitting device according to the embodiment.

FIG. 13 is a schematic cross-sectional view for illustrating a step of the method for manufacturing the light-emitting device according to the embodiment.

FIG. 14 is a schematic cross-sectional view for illustrating a step of the method for manufacturing the light-emitting device according to the embodiment.

FIG. 15 is a schematic cross-sectional view for illustrating a step of the method for manufacturing the light-emitting device according to the embodiment.

FIG. 16 is a schematic cross-sectional view for illustrating a step of the method for manufacturing the light-emitting device according to the embodiment.

FIG. 17 is a schematic cross-sectional view for illustrating a step of the method for manufacturing the light-emitting device according to the embodiment.

FIG. 18 is a schematic cross-sectional view for illustrating a step of the method for manufacturing the light-emitting device according to the embodiment.

FIG. 19 is a schematic cross-sectional view for illustrating a step of the method for manufacturing the light-emitting device according to the embodiment.

FIG. 20 is a schematic cross-sectional view for illustrating a step of a method for manufacturing a light-emitting device according to a modification of the embodiment.

FIG. 21 is a schematic cross-sectional view for illustrating a step of the method for manufacturing a light-emitting device according to the modification of the embodiment.

FIG. 22 is a schematic cross-sectional view for illustrating a step of the method for manufacturing a light-emitting device according to the modification of the embodiment.

FIG. 23 is a schematic plan view of the light-emitting device according to the modification of the embodiment.

FIG. 24 is a schematic cross-sectional view taken along line XXIV-XXIV in FIG. 23.

FIG. 25 is a schematic cross-sectional view for illustrating a step of a method for manufacturing the light-emitting device illustrated in FIGS. 23 and 24.

### DETAILED DESCRIPTION

A light-emitting device and a method for manufacturing a light-emitting device according to embodiments of the present disclosure will be described below with reference to the drawings. Embodiments described below exemplify a light-emitting device and a method for manufacturing a light-emitting device that embody the technical ideas of the present disclosure and are not limited to the following. Further, dimensions, materials, shapes, relative arrangements, or the like of constituent members described in the embodiments are not intended to limit the scope of the present disclosure thereto, unless otherwise specified, and are merely exemplary. Note that the sizes, positional relationship, or the like of members illustrated in each of the drawings may be exaggerated for clarity of description. Further, in the following description, members having the same terms and reference characters represent the same or similar members, and a detailed description of these members will be omitted as appropriate. As a cross-sectional view, an end view illustrating only a cut surface may be illustrated.

In the following description, terms indicating specific directions or positions (e.g., “on,” “above,” “upper,” “lower,” “below,” “under,” and other terms related to those terms) may be used. However, these terms are used merely to make it easy to understand relative directions or positions in the referenced drawing. As long as the relative direction or position is the same as that described in the referenced drawing using the term such as “on,” “above,” “upper,” “lower,” “below,” or “under,” in drawings other than the drawings of the present disclosure, actual products, and the like, components need not be arranged in the same manner as that in the referenced drawing. On the assumption that there are two members, a positional relationship expressed as “on,” “above,” “upper,” “lower,” “below,” or “under” in the present specification may include a case in which the two members are in contact with each other and a case in which the two members are not in contact with each other and one of the two members is located above (or below) the other member. Further, in the present specification, unless otherwise specified, a case in which a member covers an object to be covered includes a case in which the member is in contact with the object to be covered and directly covers the object to be covered, and a case in which the member is not in contact with the object to be covered and indirectly covers the object to be covered.

In the following drawings, directions are indicated by an X-axis, a Y-axis, and a Z-axis. A direction along the X-axis is referred to as a first direction X, and the first direction X indicates a predetermined direction in a light-emitting surface of a light-emitting device according to an embodiment. A direction along the Y-axis is referred to as a second direction Y, and the second direction Y is orthogonal to the first direction X in the light-emitting surface. The light-emitting surface of the light-emitting device is parallel to an XY plane. A direction along the Z-axis is referred to as a third direction Z, and the third direction Z is orthogonal to the light-emitting surface of the light-emitting device.

### Light-Emitting Device

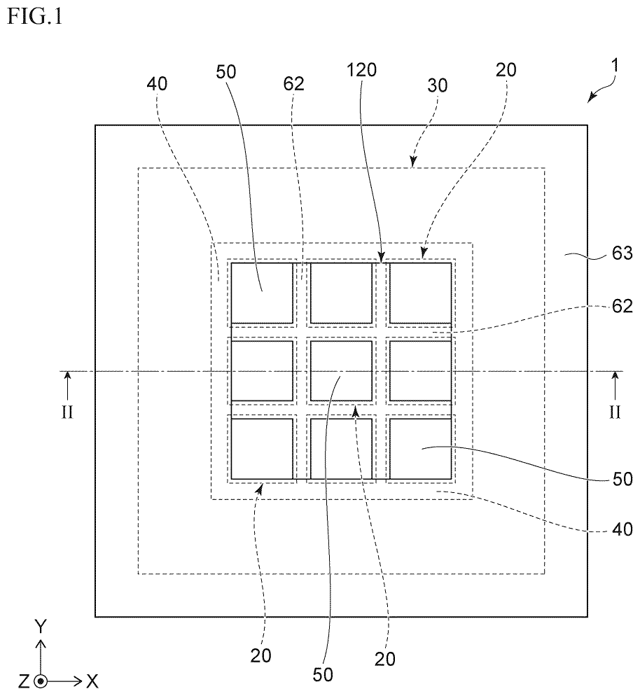

A light-emitting device 1 according to an embodiment will be described with reference to FIGS. 1 to 3. The light-emitting device 1 includes a light source unit 100. The light source unit 100 includes a plurality of semiconductor light-emitting units 20, a first resin member 40, and a non-light-emitting semiconductor portion 30.

### Semiconductor Light-Emitting Unit

The semiconductor light-emitting unit 20 includes a semiconductor structure 10 including an active layer. The semiconductor light-emitting unit 20 has a light-emitting surface 20A, which is a main extraction surface of light emitted from the active layer.

The semiconductor structure 10 includes a nitride semiconductor. In the present specification, it is assumed that examples of the nitride semiconductor include semiconductors having all compositions of a chemical formula expressed by InₓAl_{y}Ga_{1-x-y}N (0≤x≤1, 0≤y≤1, x+y≤1) in which the composition ratios of x and y are changed within the respective ranges. Further, it is assumed that examples of the nitride semiconductor also include a semiconductor further containing a group V element other than nitrogen (N) in the chemical formula described above, and a semiconductor further containing, in the chemical formula described above, various elements added to control various physical properties such as the conductivity type of the semiconductor.

The active layer has, for example, a multiple quantum well (MQW) structure including a plurality of barrier layers and a plurality of well layers. Light emitted by the active layer is visible light or ultraviolet light, for example. The plurality of semiconductor light-emitting units 20 may be composed of semiconductor light-emitting units 20 having the same light emission peak wavelength, or may include semiconductor light-emitting units 20 having different light emission peak wavelengths. For example, a plurality of semiconductor light-emitting units 20 in which variations in optical characteristics (luminance, chromaticity, and the like) fall within a predetermined range may be selected and used in the light-emitting device 1.

Electrodes 21 may be disposed on a surface of the semiconductor light-emitting unit 20 opposite to the light-emitting surface 20A in the third direction Z. At least two electrodes 21 are arranged for one semiconductor light-emitting unit 20. One of the two electrodes 21 functions as an anode electrode and the other functions as a cathode electrode.

The semiconductor light-emitting unit 20 does not include a substrate on the semiconductor structure 10. Thus, it is possible to reduce light emitted from the active layer being reflected by the substrate to return to the inside of the semiconductor structure 10, and to improve light extraction efficiency. The substrate here is a substrate for growing the semiconductor structure 10, or the like, for example.

FIG. 1 illustrates, for example, nine semiconductor light-emitting units 20 arranged in a matrix in the first direction X and the second direction Y. The arrangement and the number of the plurality of semiconductor light-emitting units 20 are not limited thereto, and can be changed according to the light emission characteristics required for the light-emitting device 1.

The light-emitting device 1 can be used as a flash light source for an imaging device, for example. The imaging device can be mounted on, for example, a mobile communication terminal. When the light-emitting device 1 is used as a flash light source for an imaging device, for example, light can be emitted by switching between a narrow-angle mode in which only the semiconductor light-emitting unit 20 disposed centrally in a plan view emits light and a wide-angle mode in which all of the semiconductor light-emitting units 20 emit light. The narrow-angle mode has a light irradiation angle narrower than the wide-angle mode. Because the light-emitting device 1 can switch the emission light according to the narrow-angle mode and the wide-angle mode, photography according to a photography mode in an imaging device, such as telescopic photography or close-up photography, is possible, for example. In the wide-angle mode, the irradiation angle can be adjusted by controlling the light emission intensity of the plurality of semiconductor light-emitting units 20.

### First Resin Member

The first resin member 40 holds the plurality of semiconductor light-emitting units 20 and the semiconductor portion 30. The first resin member 40 is disposed between adjacent ones of the semiconductor light-emitting units 20 and between the semiconductor portion 30 and the semiconductor light-emitting units 20, and covers the semiconductor light-emitting units 20 and the semiconductor portion 30. The first resin member 40 has a first resin surface 41 and a second resin surface 42 located opposite to the first resin surface 41 in the third direction Z. The first resin member 40 is not disposed on the light-emitting surfaces 20A of the semiconductor light-emitting units 20, but is disposed between the plurality of semiconductor light-emitting units 20 such that the light-emitting surfaces 20A are exposed on the first resin surface 41. The first resin member 40 covers the electrodes 21.

The first resin member 40 has insulating properties. The first resin member 40 includes a resin and a light reflective material contained in the resin. The first resin member 40 is reflective to light emitted from the active layer. As the resin of the first resin member 40, a thermosetting resin such as a silicone resin, a modified silicone resin, an epoxy resin, a modified epoxy resin, or a phenol resin can be used, for example. Among these, particularly, a silicone resin or a modified silicone resin with good light resistance and heat resistance is preferably used. As the light reflective material of the first resin member 40, titanium oxide, silicon oxide, or the like can be used, for example.

By disposing the light-reflective first resin member 40 between adjacent ones of the semiconductor light-emitting units 20, when one semiconductor light-emitting unit 20 emits light and the semiconductor light-emitting unit 20 adjacent to the one semiconductor light-emitting unit 20 does not emit light, it is possible to reduce the likelihood of irradiation, with the light emitted by the one semiconductor light-emitting unit 20, toward the semiconductor light-emitting unit 20 not emitting light. Consequently, a light-emitting device 1 having a high contrast (luminance ratio between the light-emitting region and the non-light-emitting region) can be obtained.

The first resin member 40 is located outside the plurality of semiconductor light-emitting units 20 in a plan view. Consequently, it is possible to reduce the likelihood of leakage of light to the outside of the region in which the plurality of semiconductor light-emitting units 20 are disposed, obtaining the light-emitting device 1 having a high contrast.

### Semiconductor Portion

The semiconductor portion 30 does not emit light. The semiconductor portion 30 does not include an active layer, for example. In addition, no electrodes connected to an external circuit are disposed in the semiconductor portion 30. The semiconductor portion 30 is composed of a part of a semiconductor layer (an n-side semiconductor layer as described later) constituting the semiconductor structure 10 of the semiconductor light-emitting unit 20, and transmits light emitted from the active layer of the semiconductor light-emitting unit 20.

As illustrated in FIG. 1, the semiconductor portion 30 is located outside the plurality of semiconductor light-emitting units 20 in a plan view. In the example illustrated in FIG. 1, the two portions extending in the first direction X and the two portions extending in the second direction Y are continuous. The semiconductor portion 30 surrounds the plurality of semiconductor light-emitting units 20 in a plan view. For example, the semiconductor portion 30 continuously surrounds the plurality of semiconductor light-emitting units 20 in a plan view. The region surrounded by the semiconductor portion 30 is rectangular in a plan view, for example.

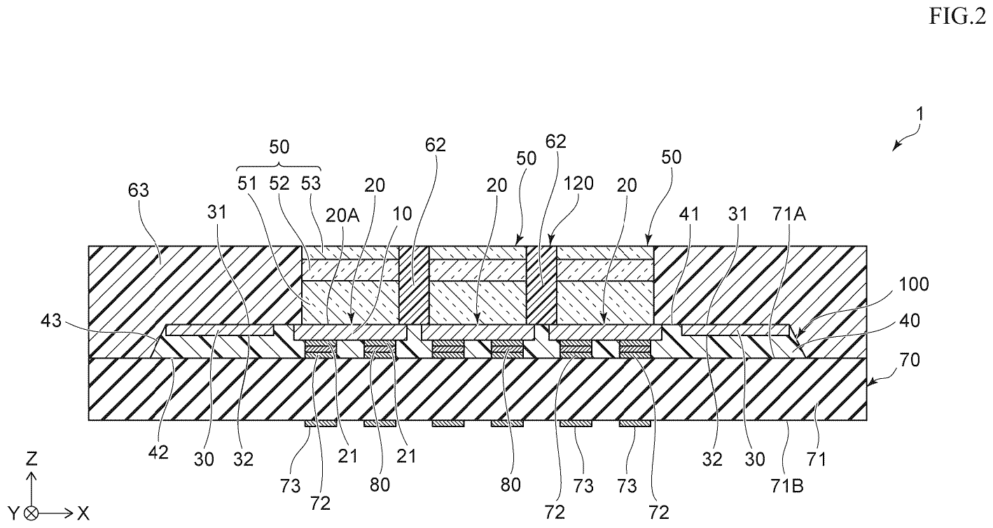

As illustrated in FIG. 2, the semiconductor portion 30 has a lower surface 32 and an upper surface 31 located opposite to the lower surface 32 in the third direction Z. The lower surface 32 is covered by the first resin member 40. The first resin member 40 is located between the lower surface 32 and the second resin surface 42. The first resin member 40 is not disposed on the upper surface 31, and the upper surface 31 is exposed from the first resin member 40.

The light source unit 100 (including the plurality of semiconductor light-emitting units 20, the first resin member 40, and the semiconductor portion 30) is separated from the substrate as described below. The light source unit 100 and the substrate are separated from each other by a laser lift-off method. At this time, the first resin surface 41 of the first resin member 40 is discolored by the irradiation with the laser light, and the light reflectance is reduced. According to the present embodiment, the area of the first resin surface 41 in the light source unit 100 can be reduced by disposing the semiconductor portion 30 in a region other than the region in which the semiconductor light-emitting units 20 are disposed. Consequently, light absorption in the light-emitting device 1 can be reduced. The light reflectance of the first resin member 40 in contact with the lower surface 32 of the semiconductor portion 30 is higher than the light reflectance of the first resin surface 41. For example, the light reflectance of the first resin member 40 in contact with the lower surface 32 of the semiconductor portion 30 is 70% or more, and the light reflectance of the first resin surface 41 is 30% or less, with respect to light having a light emission peak wavelength of 450 nm.

In a plan view, the width of the semiconductor portion 30 (the width in the second direction Y of the portion extending in the first direction X and the width in the first direction X of the portion extending in the second direction Y) is greater than the distance between the plurality of semiconductor light-emitting units 20 (the distance between the semiconductor light-emitting units 20 adjacent to each other in the first direction X and the distance between the semiconductor light-emitting units 20 adjacent to each other in the second direction Y). By disposing the semiconductor portion 30 in a region having a greater width than the region between adjacent ones of the semiconductor light-emitting units 20 on the first resin surface 41 side of the first resin member 40, it is possible to greatly reduce the area of the first resin surface 41 and to reduce the area of a portion of the first resin member 40 that is easily discolored by laser light. As a result, the light absorption can be easily reduced. The width of the semiconductor portion 30 is, for example, in a range from 30 μm to 200 μm.

The distance between adjacent ones of the semiconductor light-emitting units 20 is, for example, in a range from 1 μm to 30 μm. By setting the distance between adjacent ones of the semiconductor light-emitting units 20 in such a range, the semiconductor light-emitting units 20 having a large area in a plan view can be used while the light-emitting device 1 has a high contrast, improving the luminance of the light-emitting device 1.

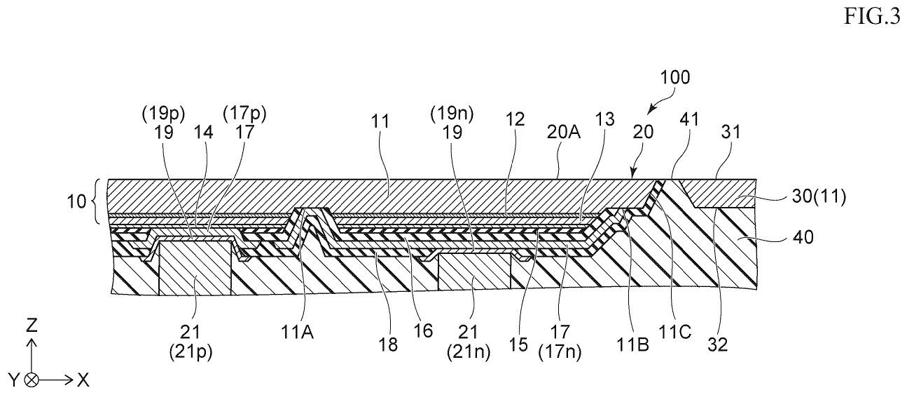

FIG. 3 illustrates a specific example of the semiconductor light-emitting unit 20 and the semiconductor portion 30.

The semiconductor structure 10 in the semiconductor light-emitting unit 20 includes an n-side semiconductor layer 11, a p-side semiconductor layer 13, and an active layer 12 located between the n-side semiconductor layer 11 and the p-side semiconductor layer 13 in the third direction Z. A surface of the n-side semiconductor layer 11 located opposite to the surface on which the active layer 12 is disposed serves as the light-emitting surface 20A. The light-emitting surface 20A and the upper surface 31 of the semiconductor portion 30 may be covered with a protective film.

The light-emitting surface 20A of the semiconductor light-emitting unit 20, the first resin surface 41 of the first resin member 40, and the upper surface 31 of the semiconductor portion 30 are on the same XY plane.

The semiconductor portion 30 does not include the p-side semiconductor layer 13 and the active layer 12, and includes the n-side semiconductor layer 11. Therefore, the thickness of the semiconductor portion 30 in the third direction Z is less than the thickness of the semiconductor structure 10 of the semiconductor light-emitting unit 20 in the third direction Z. Consequently, light absorption by the semiconductor portion 30 can be reduced.

According to the example illustrated in FIG. 3, a conductive film 14, a first insulating film 15, a second insulating film 16, a wiring layer 17, a third insulating film 18, and bonding electrodes 19 are disposed on a surface side of the semiconductor structure 10 located opposite to the light-emitting surface 20A.

The conductive film 14 is disposed on a surface of the p-side semiconductor layer 13 located opposite to the surface on which the active layer 12 is disposed, and is electrically connected to the p-side semiconductor layer 13. The conductive film 14 may be reflective to light emitted from the active layer 12. When the conductive film 14 is reflective to light emitted from the active layer 12, the conductive film 14 has a reflectance of 60% or more, preferably 70% or more, with respect to the peak wavelength of the light emitted from the active layer 12.

The first insulating film 15 is disposed over the p-side semiconductor layer 13 and covers the conductive film 14. The second insulating film 16 covers the first insulating film 15. The second insulating film 16 also covers a lateral surface of a mesa portion in which a part of the n-side semiconductor layer 11, the active layer 12, and the p-side semiconductor layer 13 are stacked.

The wiring layer 17 is formed on the second insulating film 16. The wiring layer 17 includes an n-side wiring layer 17n and a p-side wiring layer 17p. The n-side wiring layer 17n and the p-side wiring layer 17p are separated from each other on the second insulating film 16. The n-side wiring layer 17n is in contact with an n-side connecting portion 11A of the n-side semiconductor layer 11 exposed from the active layer 12 and the p-side semiconductor layer 13, and is electrically connected to the n-side semiconductor layer 11. In the example illustrated in FIG. 3, the n-side wiring layer 17n is also in contact with an outer peripheral surface 11B of the n-side semiconductor layer 11 exposed from the active layer 12 and the p-side semiconductor layer 13.

The third insulating film 18 covers the wiring layer 17. Further, the third insulating film 18 covers the outer peripheral surface 11B of the n-side semiconductor layer 11 and a lateral surface 11C of the n-side semiconductor layer 11 connected to the outer peripheral surface 11B.

The bonding electrode 19 is disposed at an opening portion formed at the third insulating film 18 and is connected to the wiring layer 17 in the opening portion. An electrode 21 in a bump shape, for example, is disposed on the bonding electrode 19. The bonding electrode 19 includes an n-side bonding electrode 19n connected to the n-side wiring layer 17n and a p-side bonding electrode 19p connected to the p-side wiring layer 17p. The electrode 21 includes an n-side electrode 21n connected to the n-side bonding electrode 19n and a p-side electrode 21p connected to the p-side bonding electrode 19p. The n-side electrode 21n is electrically connected to the n-side semiconductor layer 11 via the n-side bonding electrode 19n and the n-side wiring layer 17n.

The p-side wiring layer 17p is in contact with the conductive film 14. The p-side semiconductor layer 13 is electrically connected to the p-side electrode 21p via the conductive film 14, the p-side wiring layer 17p, and the p-side bonding electrode 19p.

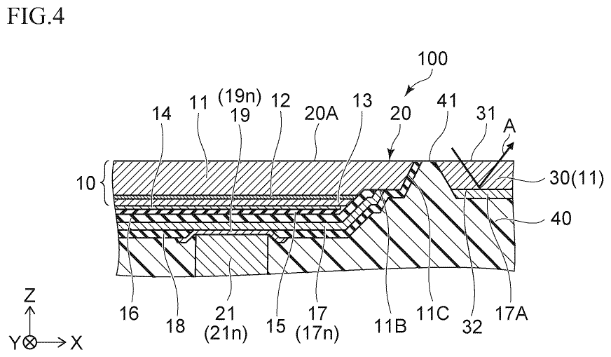

As illustrated in FIG. 4, the semiconductor portion 30 may be provided with a metal layer 17A on the lower surface 32 side. The metal layer 17A is located between the semiconductor portion 30 and the first resin member 40 in the third direction Z. Return light from above or light wavelength-converted by a light-transmissive member described below can be reflected by the metal layer 17A and directed upward as indicated by an arrow A in FIG. 4. Thus, light extraction efficiency in the light-emitting device 1 can be improved.

### Support Member

As illustrated in FIG. 2, the light-emitting device 1 may further include a support member 70 that supports the plurality of semiconductor light-emitting units 20, the semiconductor portion 30, and the first resin member 40. A surface of the semiconductor light-emitting unit 20 located opposite to the light-emitting surface 20A and the lower surface 32 of the semiconductor portion 30 face the support member 70 in the third direction Z.

The support member 70 also functions as a wiring member that electrically connects the semiconductor light-emitting units 20 and an external circuit. The support member 70 includes an insulating base body 71, a first wiring portion 72, and a second wiring portion 73. The insulating base body 71 has a third surface 71A and a fourth surface 71B. The third surface 71A faces the plurality of semiconductor light-emitting units 20, the semiconductor portion 30, and the first resin member 40 in the third direction Z. The fourth surface 71B is located opposite to the third surface 71A in the third direction Z.

The first wiring portion 72 is disposed on the third surface 71A. The electrode 21 of the semiconductor light-emitting unit 20 is bonded to the first wiring portion 72 via a conductive bonding member 80. The second wiring portion 73 is disposed on the fourth surface 71B. The second wiring portion 73 can be electrically connected to the first wiring portion 72 via a conductive member extending through the insulating base body 71, for example. The second wiring portion 73 functions as an external connection terminal electrically connected to a mounting substrate on which the light-emitting device 1 is mounted.

As the material of the insulating base body 71, aluminum nitride, aluminum oxide, or silicon nitride can be used, for example. When aluminum nitride is used as the material of the insulating base body 71, the heat dissipation of the support member 70 can be improved, and the heat generated by the light emission of the semiconductor light-emitting unit 20 can be efficiently dissipated. As the bonding member 80, solder can be used, for example.

### Second Structure

The light-emitting device 1 may further include a second structure 120 disposed on the plurality of semiconductor light-emitting units 20. The second structure 120 includes a plurality of light-transmissive members 50 and a second resin member 62 disposed between the plurality of light-transmissive members 50. The plurality of light-transmissive members 50 are integrally held by the second resin member 62.

### Light-Transmissive Member

The plurality of light-transmissive members 50 are disposed on the plurality of semiconductor light-emitting units 20, respectively. The light-transmissive members 50 each convert the wavelength of at least a part of the light emitted from the active layer of a corresponding one of the semiconductor light-emitting units 20. The light-emitting device 1 emits light in which the light emitted by the semiconductor light-emitting units 20 and the light wavelength-converted by the light-transmissive members 50 are mixed.

As illustrated in FIG. 1, in a plan view, the shape of the semiconductor light-emitting unit 20 and the shape of the light-transmissive member 50 can be square or rectangular. For example, in a plan view, an outer edge (indicated by a solid line) of the light-transmissive member 50 is located inside an outer edge (indicated by a dashed line) of the semiconductor light-emitting unit 20. In this case, the semiconductor light-emitting unit 20 can emit narrow-angle light with reduced spread of light as compared with a case in which the outer edge of the light-transmissive member 50 coincides with the outer edge of the semiconductor light-emitting unit 20 or is located outside the outer edge of the semiconductor light-emitting unit 20 in a plan view.

The outer edge of the light-transmissive member 50 may coincide with the outer edge of the semiconductor light-emitting unit 20 or may be located outside the outer edge of the semiconductor light-emitting unit 20 in a plan view.

As illustrated in FIG. 2, the light-transmissive member 50 can include a wavelength conversion layer 51 disposed on the light-emitting surface 20A of the semiconductor light-emitting unit 20, a light diffusion layer 52 disposed on the wavelength conversion layer 51, and a light-transmissive layer 53 disposed on the light diffusion layer 52.

The wavelength conversion layer 51 has a wavelength conversion function. The wavelength conversion layer 51 contains, for example, a resin the same as or similar to that of the first resin member 40 and a wavelength conversion substance. As the wavelength conversion substance, for example, an yttrium aluminum garnet-based phosphor (for example, (Y,Gd)₃(Al,Ga)₅O₁₂:Ce), a lutetium aluminum garnet-based phosphor (for example, Lu₃(Al,Ga)₅O₁₂:Ce), a terbium aluminum garnet-based phosphor (for example, Tb₃(Al,Ga)₅O₁₂:Ce), a CCA-based phosphor (for example, Ca₁₀(PO₄)₆Cl₂:Eu), an SAE-based phosphor (for example, Sr₄Al₁₄O₂₅:Eu), a chlorosilicate-based phosphor (for example, Ca₈MgSi₄O₁₆Cl₂:Eu), a silicate-based phosphor (for example, (Ba,Sr,Ca,Mg)₂SiO₄:Eu), an oxynitride-based phosphor such as a β-SiAlON-based phosphor (for example, (Si,Al)₃(O,N)₄:Eu) or an α-SiAlON-based phosphor (for example, Ca(Si,Al)₁₂(O,N)₁₆:Eu), a nitride-based phosphor such as an LSN-based phosphor (for example, (La, Y)₃Si₆N₁₁:Ce), a BSESN-based phosphor (for example, (Ba,Sr)₂Si₅N₈:Eu), an SLA-based phosphor (for example, SrLiAl₃N₄:Eu), a CASN-based phosphor (for example, CaAlSiN₃:Eu), or an SCASN-based phosphor (for example, (Sr,Ca) AlSiN₃:Eu), a fluoride-based phosphor such as a KSF-based phosphor (for example, K₂SiF₆:Mn), a KSAF-based phosphor (for example, K₂(Si₁₋ₓAlₓ)F₆₋ₓ:Mn, where x satisfies 0<x<1), or an MGF-based phosphor (for example, 3.5MgO·0.5MgF₂·GeO₂:Mn), a quantum dot having a perovskite structure (for example, (Cs,FA,MA)(Pb,Sn)(F,Cl,Br,I)₃, where FA and MA represent formamidinium and methylammonium, respectively), a II-VI quantum dot (for example, CdSe), a III-V quantum dot (for example, InP), a quantum dot having a chalcopyrite structure (for example, (Ag,Cu)(In,Ga)(S,Se)₂), or the like can be used.

The wavelength conversion layer 51 may contain one type of wavelength conversion substance, or may contain a plurality of types of wavelength conversion substances.

The light diffusion layer 52 diffuses light emitted by the semiconductor light-emitting unit 20 and light wavelength-converted by the wavelength conversion layer 51. The light diffusion layer 52 may contain, for example, a base material resin the same as or similar to that of the first resin member 40 and a light diffusion substance. As the light diffusion substance, titanium oxide or silicon oxide can be used, for example. Due to the light diffusion layer 52, the body color of the light-transmissive member 50 and the body color of the second resin member 62 can be brought close to each other when the light-emitting device 1 is viewed from the light-emitting surface side during non-light emission, and the light-emitting device can have a good appearance during non-light emission. The concentration of the light diffusion substance in the light diffusion layer 52 is preferably lower than the concentration of the light reflective material in the second resin member 62. Thus, light can be easily extracted from the light-transmissive member 50.

The light-transmissive layer 53 may contain, for example, a resin the same as or similar to that of the first resin member 40. The transmittance of the light-transmissive layer 53 is higher than the transmittance of the light diffusion layer 52 with respect to light emitted by the semiconductor light-emitting unit 20 and light wavelength-converted by the wavelength conversion layer 51. The light-transmissive layer 53 does not contain a light diffusion substance, for example.

### Second Resin Member

The second resin member 62 is disposed between the light-transmissive members 50 adjacent to each other in the first direction X, and between the light-transmissive members 50 adjacent to each other in the second direction Y. The second resin member 62 is reflective to light emitted by the semiconductor light-emitting unit 20 and light wavelength-converted by the light-transmissive member 50. The second resin member 62 may have, for example, a configuration the same as or similar to that of the first resin member 40.

By disposing the second resin member 62 disposed between adjacent ones of the light-transmissive members 50, when one semiconductor light-emitting unit 20 emits light and the semiconductor light-emitting unit 20 adjacent to the one semiconductor light-emitting unit 20 does not emit light, the light emitted by the one semiconductor light-emitting unit 20 is less likely to be incident on the light-transmissive member 50 on the semiconductor light-emitting unit 20 not emitting light. Thus the wavelength conversion substance contained in the light-transmissive member 50 on the semiconductor light-emitting unit 20 not emitting light can be suppressed from emitting light. Consequently, the light-emitting device 1 having a high contrast can be obtained.

In the example illustrated in FIG. 2, the second resin member 62 does not cover the outer lateral surface of the light-transmissive member 50 located on the outermost side in the first direction X. In addition, the second resin member 62 does not cover the outer lateral surface of the light-transmissive member 50 located on the outermost side in the second direction Y. The light-emitting device of the present disclosure is not limited thereto, and the second resin member 62 may cover the outer lateral surface of the outermost light-transmissive member 50 in a plan view.

### Third Resin Member

The light-emitting device 1 may further include a third resin member 63. The third resin member 63 is disposed on an outer peripheral portion of the third surface 71A of the insulating base body 71 on which the light source unit 100 is not disposed, and covers a lateral surface 43 of the first resin member 40. The third resin member 63 is disposed on the upper surface 31 of the semiconductor portion 30 and covers the upper surface 31 of the semiconductor portion 30.

The third resin member 63 is reflective to light emitted by the semiconductor light-emitting unit 20 and light wavelength-converted by the light-transmissive member 50. The third resin member 63 can reduce the likelihood of emission of light to a region outside the region in which the plurality of semiconductor light-emitting units 20 are disposed, allowing the light-emitting device 1 to have a high contrast.

The third resin member 63 is further located outside the plurality of light-transmissive members 50 in a plan view, and covers the outermost lateral surfaces of the light-transmissive members 50. Consequently, it is possible to reduce the likelihood of emission of light to a region outside the region in which the plurality of light-transmissive members 50 are disposed, allowing the light-emitting device 1 to have a high contrast.

The third resin member 63 may have, for example, a configuration the same as or similar to that of the second resin member 62. Consequently, the body color of the second resin member 62 and the body color of the third resin member 63 can be brought close to each other in a plan view, and the light-emitting device can have a good appearance during non-light emission.

### Method for Manufacturing Light-Emitting Device

A method for manufacturing a light-emitting device according to the embodiment will be described with reference to FIGS. 5 to 19.

The method for manufacturing a light-emitting device according to the embodiment includes providing a first structure, disposing the first structure on a support member, disposing a first resin member between the first structure and the support member, and separating a substrate from a plurality of semiconductor light-emitting units and a semiconductor portion.

### Step of Providing First Structure

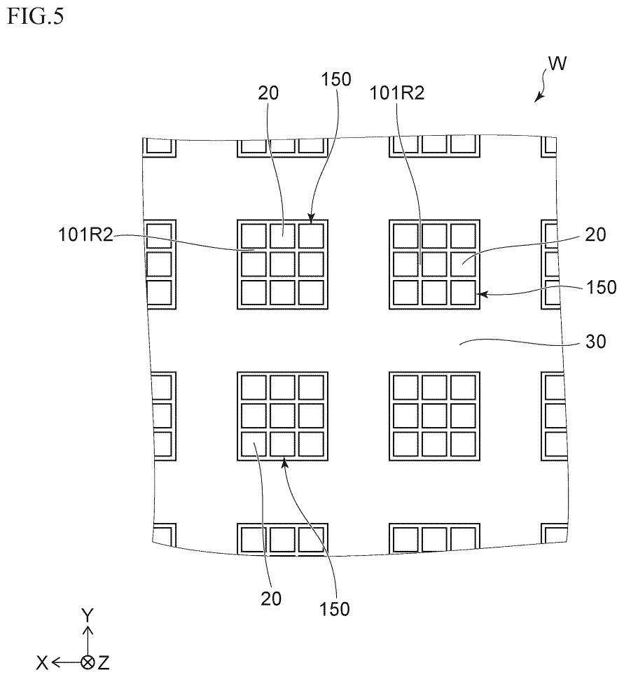

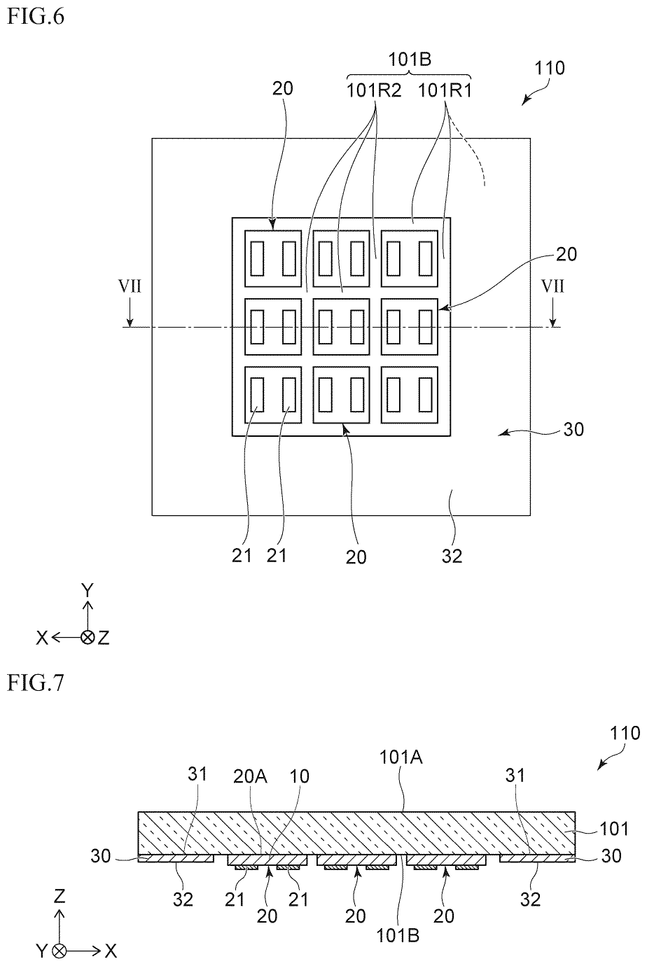

As illustrated in FIGS. 6 and 7, a first structure 110 includes a substrate 101, a plurality of semiconductor light-emitting units 20, and a non-light-emitting semiconductor portion 30.

The substrate 101 has a first surface 101A and a second surface 101B located opposite to the first surface 101A in the third direction Z. The substrate 101 is, for example, a sapphire substrate.

The plurality of semiconductor light-emitting units 20 are disposed on the second surface 101B of the substrate 101. The light-emitting surface 20A of the semiconductor light-emitting units 20 faces the second surface 101B in the third direction Z. The plurality of semiconductor light-emitting units 20 are disposed on the second surface 101B so as to be separated from each other in the first direction X and the second direction Y.

The semiconductor portion 30 is disposed in a region of the second surface 101B in which the plurality of semiconductor light-emitting units 20 are not disposed. As illustrated in FIG. 6, the region of the second surface 101B in which the plurality of semiconductor light-emitting units 20 are not disposed includes an outer peripheral region 101R1 surrounding the plurality of semiconductor light-emitting units 20 and an inter-semiconductor light-emitting unit region 101R2 between the plurality of semiconductor light-emitting units 20 in a plan view. The inter-semiconductor light-emitting unit region 101R2 includes a region between the semiconductor light-emitting units 20 adjacent to each other in the first direction X, a region between the semiconductor light-emitting units 20 adjacent to each other in the second direction Y, and a region between the semiconductor light-emitting units 20 adjacent to each other in a direction inclined with respect to the first direction X and the second direction Y (direction diagonal to the semiconductor light-emitting units 20). In the example illustrated in FIG. 6, the inter-semiconductor light-emitting unit region 101R2 has a grid shape in a plan view. The inner lateral surface of the semiconductor portion 30 is separated from the semiconductor light-emitting units 20 in the first direction X and the second direction Y and faces the semiconductor light-emitting units 20.

The first structure 110 can be provided, for example, by singulation of a wafer W illustrated in FIG. 5. The wafer W includes a substrate 101, a plurality of semiconductor light-emitting units 20, and a semiconductor portion 30. The wafer W can be provided by forming a semiconductor layer on the second surface 101B of the substrate 101 by, for example, a metal organic chemical vapor deposition (MOCVD) method, and then dividing the semiconductor layer formed on the second surface 101B into a plurality of semiconductor layers to be a plurality of semiconductor structures 10 and a semiconductor layer to be the semiconductor portion 30 by, for example, etching such as reactive ion etching (RIE).

In the wafer W, the semiconductor portion 30 extends in the first direction X and the second direction Y while separating a plurality of light-emitting regions 150. In each of the light-emitting regions 150, a plurality of semiconductor light-emitting units 20 (nine semiconductor light-emitting units 20 in the example in FIG. 5) are arranged separated from each other.

The wafer W is cut along the first direction X and the second direction Y at the position of the semiconductor portion 30 to be divided into the first structure 110 illustrated in FIG. 6. For example, a modified portion is formed in the substrate 101 along the first direction X and the second direction Y by laser light radiation, the inside of the substrate 101 in a region overlapping, in a plan view, the position in the wafer W in which the semiconductor portion 30 is disposed. For example, the modified portion is formed in a lattice shape in a plan view. The wafer W can be cut by applying a pressing force to the wafer W on which the modified portion has been formed.

In the wafer W illustrated in FIG. 5, the interval between adjacent ones of the light-emitting regions 150 is an interval necessary to cut the wafer W. For example, the interval between adjacent ones of the light-emitting regions 150 is larger than the interval between adjacent ones of the semiconductor light-emitting units 20 in the light-emitting region 150 (the width of the inter-semiconductor light-emitting unit region 101R2). Thus, the width of the semiconductor portion 30 that separates the plurality of light-emitting regions 150 is greater than the interval between adjacent ones of the semiconductor light-emitting units 20 in each of the light-emitting regions 150 (the width of the inter-semiconductor light-emitting unit region 101R2). Further, in the first structure 110 illustrated in FIG. 6 after singulation, the width of the outer peripheral region 101R1 is greater than the width of the inter-semiconductor light-emitting unit region 101R2. The semiconductor portion 30 is disposed in the outer peripheral region 101R1.

In the wafer W, the semiconductor layer formed on the second surface 101B includes an n-side semiconductor layer 11 located on the second surface 101B, an active layer 12 located on the n-side semiconductor layer 11, and a p-side semiconductor layer 13 located on the active layer 12. Thereafter, in the semiconductor light-emitting units 20, a part of the p-side semiconductor layer 13 and a part of the active layer 12 are removed in order to expose a part of the n-side semiconductor layer 11 (the n-side connecting portion 11A, the outer peripheral surface 11B, and the like) to be in contact with the wiring layer 17. Also, at this time, in a semiconductor layer to be the semiconductor portion 30, the p-side semiconductor layer 13 and the active layer 12 are removed. Thus, as described above with reference to FIG. 3, the semiconductor portion 30 that does not include the p-side semiconductor layer 13 and the active layer 12 and includes the n-side semiconductor layer 11 is formed. Thereafter, separation between the semiconductor portion 30 and the plurality of semiconductor light-emitting units 20 is performed by forming the inter-semiconductor light-emitting unit region 101R2 by removing portions of the semiconductor layer other than portions to be the plurality of semiconductor light-emitting units 20 and portions of the semiconductor layer other than a portion to be the semiconductor portion 30. Therefore, the thickness of the semiconductor portion 30 is less than the thickness of each of the semiconductor light-emitting units 20 including the p-side semiconductor layer 13 and the active layer 12. This facilitates cutting of the wafer W in the position of the semiconductor portion 30.

In the wafer W, the conductive film 14, the first insulating film 15, the second insulating film 16, the wiring layer 17, the third insulating film 18, and the bonding electrodes 19 described above and illustrated in FIG. 3 are formed in the semiconductor light-emitting unit 20. In the step of forming the wiring layer 17, as illustrated in FIG. 4, a metal layer 17A can be formed on the lower surface 32 of the semiconductor portion 30. The metal layer 17A can be formed of, for example, the same material as that of the wiring layer 17 disposed in the semiconductor light-emitting unit 20 at the same time. This can improve the efficiency of the step.

In addition, the electrode 21 can be formed on a surface of the semiconductor light-emitting unit 20 opposite to the light-emitting surface 20A in a state that the semiconductor light-emitting unit 20 is disposed on the wafer W.

### Step of Disposing First Structure on Support Member

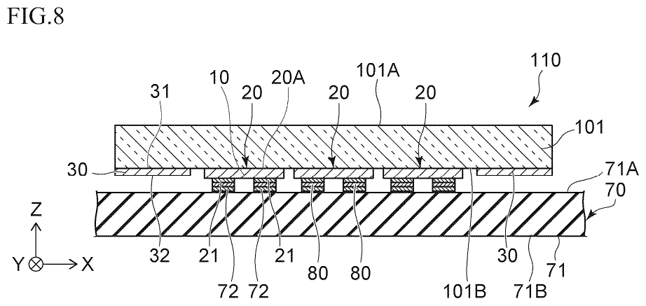

As illustrated in FIG. 8, the first structure 110 is disposed on the support member 70 such that the second surface 101B of the substrate 101 faces the support member 70. The electrode 21 is bonded to the first wiring portion 72 disposed on the third surface 71A of the support member 70 via the bonding member 80.

### Step of Disposing First Resin Member between First Structure and Support Member

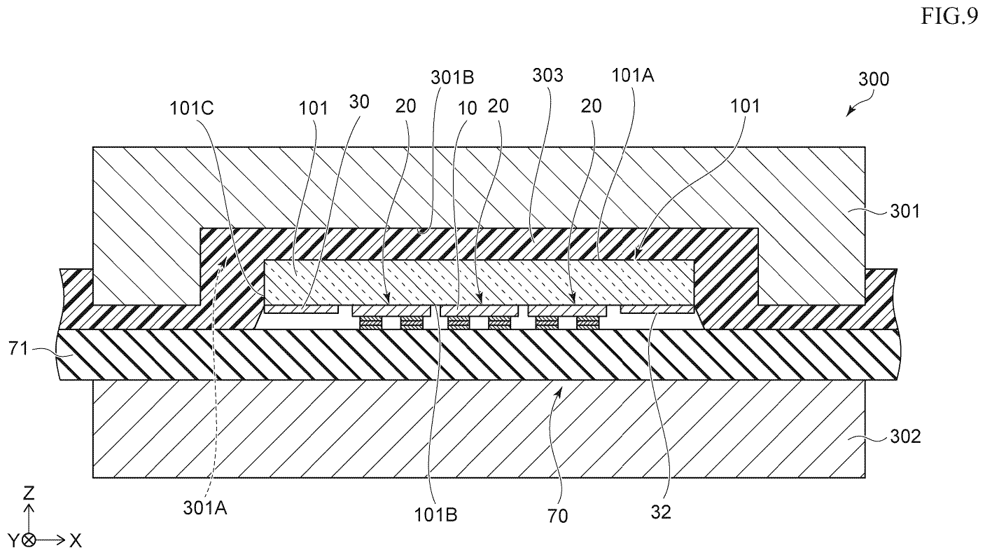

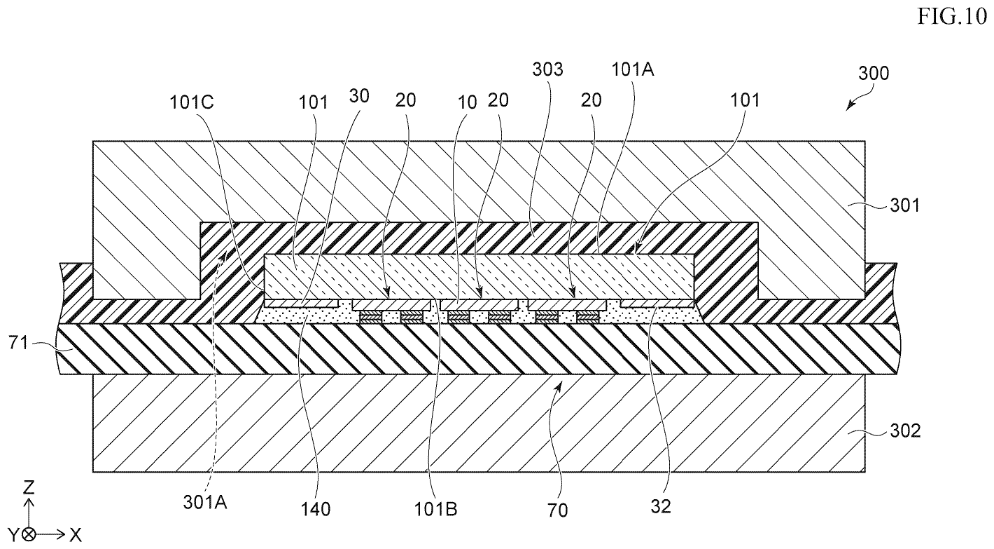

For example, the first resin member 40 can be disposed between the first structure 110 and the support member 70 with use of a mold 300 illustrated in FIGS. 9 and 10.

As illustrated in FIG. 9, the mold 300 includes an upper mold 301 and a lower mold 302. The upper mold 301 defines a recess 301A. The first structure 110 is disposed between the upper mold 301 and the lower mold 302. The support member 70 is disposed on the lower mold 302. The first surface 101A of the substrate 101 faces an upper inner wall surface 301B of the upper mold 301 defining the recess 301A.

In the recess 301A, at least the first surface 101A of the substrate 101 is covered by a covering member 303. A part of the covering member 303 extends to the outside of the recess 301A and is sandwiched between the lower end portion of the upper mold 301 and the upper surface of the lower mold 302. The covering member 303 may cover a lateral surface 101C of the substrate 101 in addition to the first surface 101A of the substrate 101. The covering member 303 is not disposed between the second surface 101B of the substrate 101 and the support member 70. The covering member 303 is, for example, a resin film formed of a fluorine-based material. The thicknesses of the covering member 303 is, for example, in a range from 100 μm to 300 μm. The unevenness followability of the covering member 303 is improved by using, as the covering member 303, a resin film that is thicker than a mold release resin film that is generally used in die molding. Consequently, it is possible to reduce the likelihood of flowing and entering of a resin material 140 described below between the first surface 101A of the substrate 101 and the covering member 303.

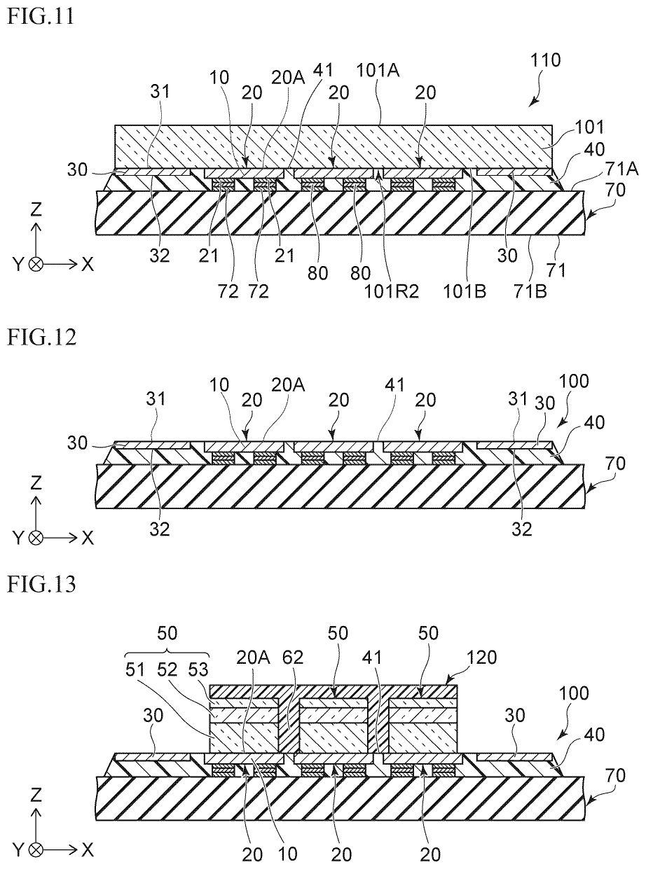

In a state in which the first surface 101A of the substrate 101 is covered by the covering member 303, as illustrated in FIG. 10, the resin material 140 having fluidity is supplied into the mold 300. For example, the liquid resin material 140 is supplied into the mold 300. Thereafter, the resin material 140 is cured by heating, for example. After the resin material 140 is cured, the upper mold 301 is moved upward, and the covering member 303 is removed. Consequently, as illustrated in FIG. 11, the first resin member 40 obtained by curing the resin material 140 is disposed between the first structure 110 and the support member 70.

The first resin member 40 is disposed in the inter-semiconductor light-emitting unit region 101R2 and covers the second surface 101B of the substrate 101 and the lateral surface of the semiconductor light-emitting unit 20 in the inter-semiconductor light-emitting unit region 101R2. The first resin member 40 is disposed between the lower surface 32 of the semiconductor portion 30 and the support member 70 and covers the lower surface 32 of the semiconductor portion 30. The first resin member 40 is disposed between the semiconductor portion 30 and the semiconductor light-emitting unit 20, and covers the second surface 101B of the substrate 101, the lateral surface of the semiconductor light-emitting unit 20, and the lateral surface of the semiconductor portion 30, at a position between the semiconductor portion 30 and the semiconductor light-emitting unit 20. The first resin member 40 covers the outermost surface of the semiconductor portion 30. The first resin member 40 covers the lateral surface of the electrode 21, the lateral surface of the bonding member 80, and the lateral surface of the first wiring portion 72.

### Step of Separating Substrate from Plurality of Semiconductor Light-Emitting Units and Semiconductor Portion

The substrate 101 is a sapphire substrate, and the semiconductor light-emitting units 20 and the semiconductor portion 30 contain gallium nitride (GaN), for example. In this case, a laser lift-off method can be used in a step of separating the substrate 101 from the plurality of semiconductor light-emitting units 20 and the semiconductor portion 30.

In the laser lift-off method, the light-emitting surface 20A of the semiconductor light-emitting unit 20 and the upper surface 31 of the semiconductor portion 30 are irradiated with laser light from the first surface 101A side of the substrate 101. The laser light has a wavelength that allows the laser light to transmit through the substrate 101 and allows the semiconductor light-emitting unit 20 and the semiconductor portion 30 to absorb the laser light. The laser light is, for example, light having a light emission peak wavelength in a range from 190 nm to 380 nm. Gallium nitride absorbs the energy of the laser light and is thermally decomposed. By the irradiation with the laser light, gallium nitride is decomposed into nitrogen and gallium on the light-emitting surface 20A of the semiconductor light-emitting unit 20 and the upper surface 31 of the semiconductor portion 30, and the substrate 101 is separated from the plurality of semiconductor light-emitting units 20 and the semiconductor portion 30. The substrate 101 can also be detached from the first resin member 40 by gas (nitrogen gas) generated at the time of decomposition.

Because the first surface 101A of the substrate 101 is covered by the covering member 303 in the step of disposing the first resin member 40 described above, the first resin member 40 is not disposed on the first surface 101A of the substrate 101. Even if the resin material 140 flows and enters between the first surface 101A of the substrate 101 and the covering member 303, the amount of the first resin member 40 disposed on the first surface 101A of the substrate 101 can be reduced as compared with a case in which the covering member 303 is not used. Because the amount of the first resin member 40 on the first surface 101A can be reduced, the likelihood of absorption or scattering of the laser light by the first resin member 40 when the laser lift-off method is used can be reduced on the first surface 101A of the substrate 101. Thus, unevenness of laser light irradiation can be reduced, and the substrate 101 can be easily separated.

When the resin material 140 flows and enters between the first surface 101A of the substrate 101 and the covering member 303, a step of removing the first resin member 40 disposed on the first surface 101A is preferably included. For example, the first resin member 40 disposed on the first surface 101A can be removed by a wet blasting process. In the wet blasting process, a solution containing an abrasive is jetted toward the first surface 101A, and the first resin member 40 disposed on the first surface 101A can be removed by the impact force. When the amount of the first resin member 40 disposed on the first surface 101A is large, the removal rate of the first resin member 40 can be increased by increasing the jet force of the solution containing the abrasive. However, when the jet force of the solution containing the abrasive is increased, the first surface 101A of the substrate 101 is easily damaged, and the laser light when the laser lift-off method is used is easily scattered or reflected by the first surface 101A. Consequently, a portion of the gallium nitride layer may remain undecomposed at the interface between the second surface 101B and the light-emitting surface 20A of the semiconductor light-emitting unit 20 and at the interface between the second surface 101B and the upper surface 31 of the semiconductor portion 30. When the substrate 101 is separated in this state, stress is applied to a part of the gallium nitride layer remaining undecomposed, and chipping or the like may occur in the semiconductor light-emitting unit 20 and the semiconductor portion 30.

According to the present embodiment, because the first surface 101A is covered by the covering member 303 in the step of disposing the first resin member 40 as described above, even if the first resin member 40 is disposed on the first surface 101A, the jet force of the solution containing the abrasive can be reduced, the first surface 101A is less likely to be damaged, and scattering or reflection of the laser light by the first surface 101A when the laser lift-off method is used can be reduced. Thus, unevenness of laser light irradiation can be reduced, and the substrate 101 can be easily separated.

As a material of the first resin member 40 suitable for detachment of the substrate 101 by the laser lift-off method, a silicone resin or an epoxy resin can be used. After the irradiation of the laser light, the substrate 101 can be separated from the plurality of semiconductor light-emitting units 20, the semiconductor portion 30, and the first resin member 40 by being sucked and lifted upward by a nozzle, for example. At this time, there is a possibility that the first resin member 40 is also pulled by the substrate 101 and lifted upward. If the force applied when the first resin member 40 is lifted is applied to the outer peripheral portion of the semiconductor light-emitting unit 20, chipping may occur at the outer peripheral portion of the semiconductor light-emitting unit 20. Because the adhesive force of the silicone resin to the substrate 101 is weaker than that of the epoxy resin, when the silicone resin is used as the material of the first resin member 40, the first resin member 40 is less likely to be pulled by the substrate 101 and the outer peripheral portion of the semiconductor light-emitting unit 20 is less likely to be chipped than when the epoxy resin is used. Preferably, a modified silicone resin such as an SMC resin, for example, can be used as the silicone resin. Modified silicone resins such as SMC resins have higher hardness than epoxy resins. Therefore, when a modified silicone resin such as an SMC resin is used as the material of the first resin member 40, the first resin member 40 is more resistant to an impact applied when the substrate 101 is separated and cracks or the like are less likely to be generated in the first resin member 40 than when an epoxy resin is used.

In the laser lift-off method, the interface between the second surface 101B of the substrate 101 and the first resin member 40 is also radiated with laser light. Consequently, a light absorbing portion that absorbs the energy of the laser light to be altered and has high light absorbency is formed on the first resin surface 41 side of the first resin member 40 that is in contact with the substrate 101.

According to the present embodiment, the semiconductor portion 30 is disposed in a region of the second surface 101B of the substrate 101 in which the plurality of semiconductor light-emitting units 20 are not disposed, reducing the area of the first resin member 40 irradiated with the laser light when the laser lift-off method is used. Consequently, the area of the light absorbing portion in a plan view is reduced, and a light-emitting device with reduced light absorption can be manufactured.

As described above, the semiconductor portion 30 is disposed in the outer peripheral region 101R1 that is wider than the inter-semiconductor light-emitting unit region 101R2, in the region of the second surface 101B of the substrate 101 in which the plurality of semiconductor light-emitting units 20 are not disposed. Consequently, the area of the first resin member 40 irradiated with the laser light by the laser lift-off method can be greatly reduced.

By separating the substrate 101 from the plurality of semiconductor light-emitting units 20, the semiconductor portion 30, and the first resin member 40, as illustrated in FIG. 12, the light source unit 100 in which the substrate 101 has been removed from the first structure 110 is obtained. In the light source unit 100, the light-emitting surface 20A of the semiconductor light-emitting unit 20 and the upper surface 31 of the semiconductor portion 30 are exposed from the first resin member 40.

The exposed light-emitting surface 20A of the semiconductor light-emitting unit 20 can be subjected to a surface roughening process. Thus, the efficiency of light extraction from the light-emitting surface 20A can be improved. The surface roughening process can be performed by, for example, a reactive ion etching (RIE) method in which a chlorine-containing gas is used or wet etching in which an alkaline solution such as tetramethylammonium hydroxide (TMAH) is used.

### Step of Disposing Second Structure

The method for manufacturing a light-emitting device according to the embodiment may further include a step of disposing a second structure 120 on the plurality of semiconductor light-emitting units 20 as illustrated in FIG. 13 after separation of the substrate 101.

As described above, the second structure 120 includes a plurality of light-transmissive members 50 and a second resin member 62 disposed between the plurality of light-transmissive members 50. As described above, the light-transmissive member 50 includes a wavelength conversion layer 51 disposed on the light-emitting surface 20A of the semiconductor light-emitting unit 20, a light diffusion layer 52 disposed on the wavelength conversion layer 51, and a light-transmissive layer 53 disposed on the light diffusion layer 52. The second resin member 62 covers the upper surface of the light-transmissive layer 53.

In the step of disposing the second structure 120, for example, the second structure 120 can be disposed on the light-emitting surface 20A of the semiconductor light-emitting unit 20 via an adhesive layer. Alternatively, the second structure 120 may be directly bonded to the light-emitting surface 20A of the semiconductor light-emitting unit 20.

### Step of Disposing Third Resin Member

The method for manufacturing a light-emitting device according to the embodiment may further include a step of disposing a third resin member 63 after the step of disposing the second structure 120.

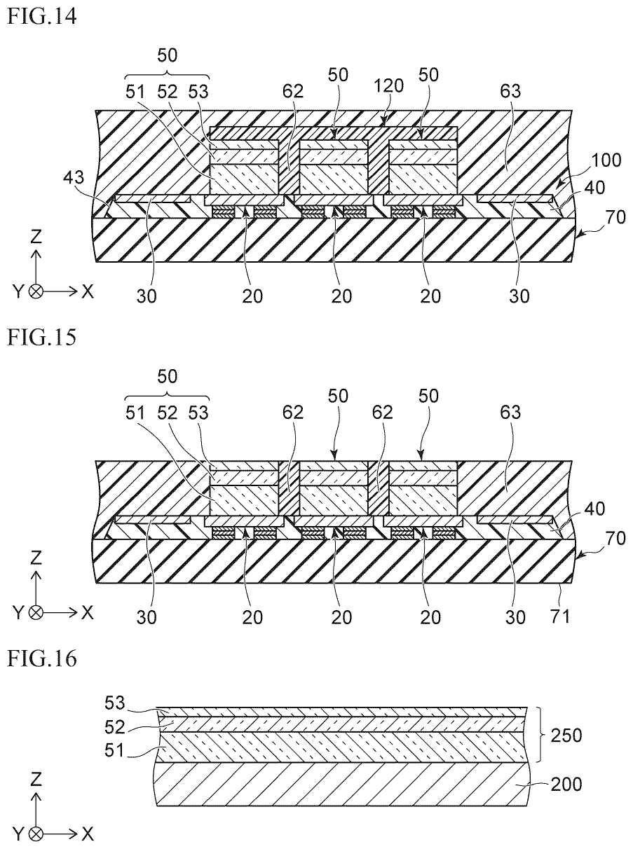

In the step of disposing the third resin member 63, as illustrated in FIG. 14, a third resin member 63 is disposed on the support member 70 so as to cover the second structure 120 and the light source unit 100.

The method may further include a step of partially removing the third resin member 63 and the second resin member 62 covering the upper surface of the light-transmissive layer 53 at the same time, after the third resin member 63 is disposed. At this time, a part of the upper surface side of the light-transmissive layer 53 may also be removed at the same time. For example, the third resin member 63 and the second resin member 62 are partially removed using a grinding device or the like. Consequently, as illustrated in FIG. 15, the upper surface of the light-transmissive layer 53 is exposed from the second resin member 62 and the third resin member 63. The upper surface of the light-transmissive layer 53, the upper surface of the second resin member 62, and the upper surface of the third resin member 63 are on the same XY plane.

By partially removing the second resin member 62 and the third resin member 63 at the same time, the number of steps can be reduced as compared with a case in which the respective resin members are removed in separate steps. In the step of removing the second resin member 62 and the third resin member 63, the light-transmissive layer 53 functions as a layer that helps prevent the light diffusion layer 52 from being removed. Because the light diffusion layer 52 is not removed, variations in the thickness of the light diffusion layer 52 can be reduced. Consequently, it is possible to reduce variations in the light diffusion function among a plurality of light-emitting units each including the semiconductor light-emitting unit 20 and the light-transmissive member 50. In addition, it is possible to reduce variations in color among the plurality of light-emitting units during non-light emission in a plan view, and the light-emitting device can have a good appearance during non-light emission.

After the step in FIG. 15, for example, a blade is used to cut the third resin member 63 and the insulating base body 71 of the support member 70 in the region in which the first resin member 40 is not disposed, whereby singulation is performed to obtain the light-emitting device 1 illustrated in FIG. 2.

The second structure 120 can be provided through the steps described below with reference to FIGS. 16 to 19.

In the step illustrated in FIG. 16, a wavelength conversion sheet 250 is disposed on a sheet-like or plate-like support 200. The wavelength conversion sheet 250 includes a wavelength conversion layer 51 disposed on the support 200, a light diffusion layer 52 disposed on the wavelength conversion layer 51, and a light-transmissive layer 53 disposed on the light diffusion layer 52.

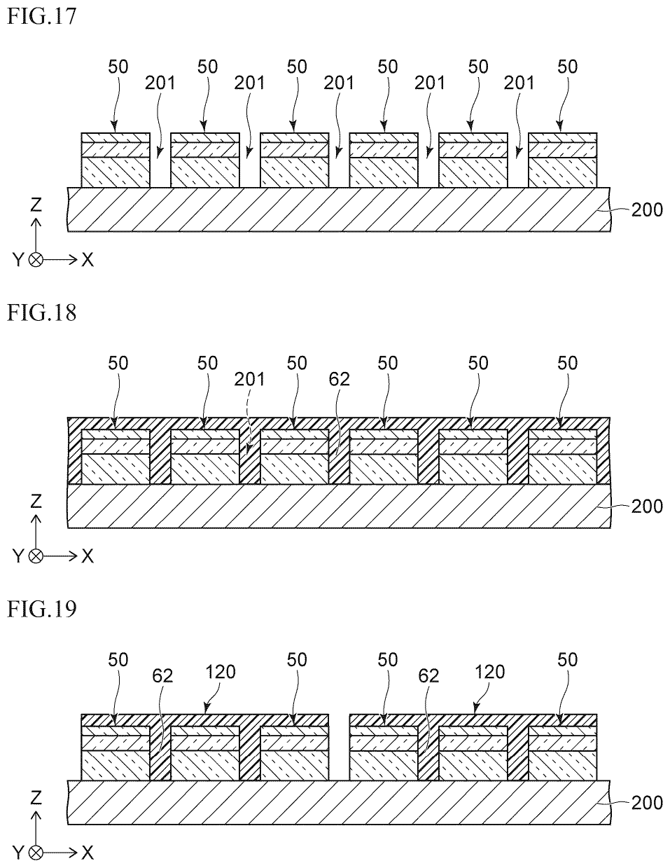

In the step illustrated in FIG. 17, the wavelength conversion sheet 250 is divided into a plurality of light-transmissive members 50. For example, grooves 201 are formed in the wavelength conversion sheet 250 by blade processing or laser processing, and the wavelength conversion sheet 250 is divided into a plurality of light-transmissive members 50.

In the step illustrated in FIG. 18, a second resin member 62 is disposed on the support 200 so as to cover the plurality of light-transmissive members 50. The second resin member 62 is disposed by, for example, compression molding in which a mold is used. The second resin member 62 is also disposed in the grooves 201 each between adjacent ones of the light-transmissive members 50.

In the step illustrated in FIG. 19, the second resin member 62 is cut and divided into a plurality of second structures 120 by, for example, blade processing or laser processing.

The step of disposing the second structure 120 may include a step of disposing the plurality of light-transmissive members 50 such that the light-transmissive members 50 respectively overlap the semiconductor light-emitting units 20 in a plan view, and then a step of disposing the second resin member 62 between the plurality of light-transmissive members 50.

### Modification of Method for Manufacturing Light-Emitting Device

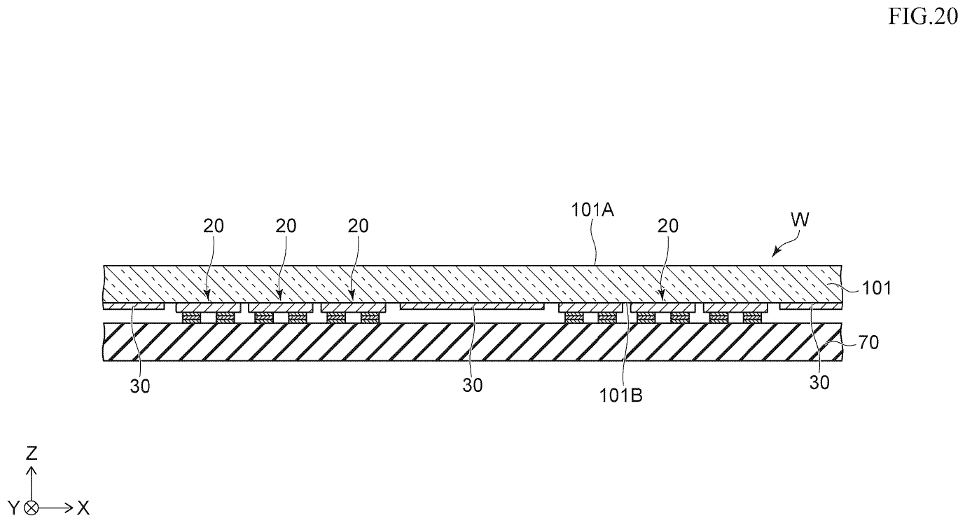

A method for manufacturing a light-emitting device according to a modification will be described with reference to FIGS. 20 to 22.

As illustrated in FIG. 20, the wafer W described above with reference to FIG. 5 is disposed on the support member 70. In this example, a wiring member included as a part of the light-emitting device is indicated as the support member 70, but the support member may be one temporarily used in the manufacture process.

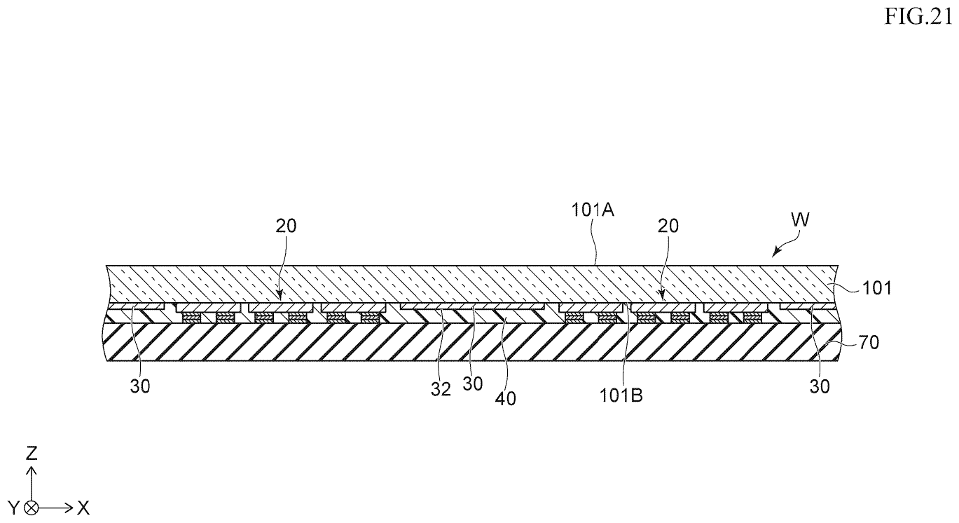

After the wafer W is disposed on the support member 70, as illustrated in FIG. 21, a first resin member 40 is disposed between the wafer W and the support member 70. As described above, the first resin member 40 can be disposed using a mold.

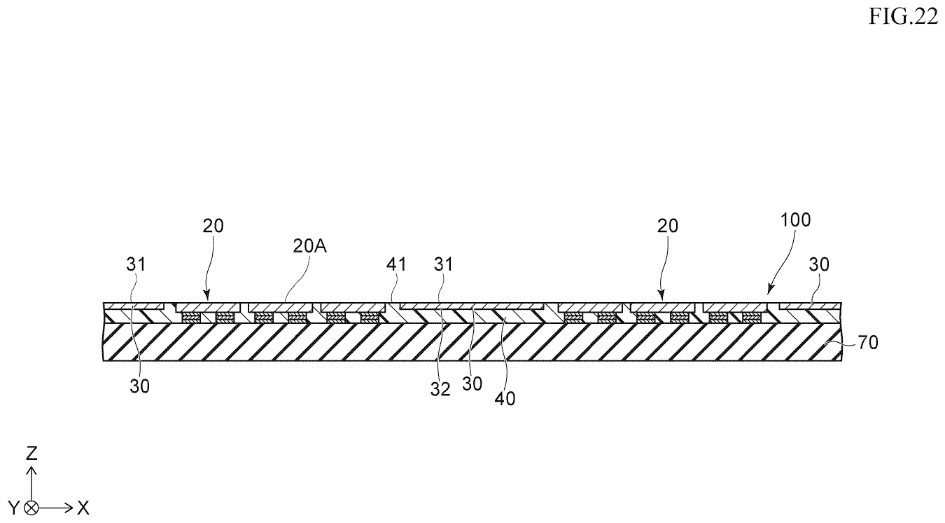

After the first resin member 40 is disposed, the substrate 101 is separated from the plurality of semiconductor light-emitting units 20, the semiconductor portion 30, and the first resin member 40. As described above, the substrate 101 can be separated by a laser lift-off method. By separation of the substrate 101, as illustrated in FIG. 22, a light source unit 100 in a wafer form is obtained. In the light source unit 100 in a wafer form, the light-emitting surfaces 20A of the plurality of semiconductor light-emitting units 20, the upper surface 31 of the semiconductor portion 30, and the first resin surface 41 of the first resin member 40 are exposed.

After the substrate 101 is separated, the semiconductor portion 30 and the first resin member 40 covering the lower surface 32 of the semiconductor portion 30 are cut in the position of the semiconductor portion 30 using, for example, a blade or a laser. Thus, the plurality of light source units 100 are separated on the support member 70. Thereafter, steps the same as or similar to those in FIGS. 13 to 15 can follow.

### Modification of Light-Emitting Device

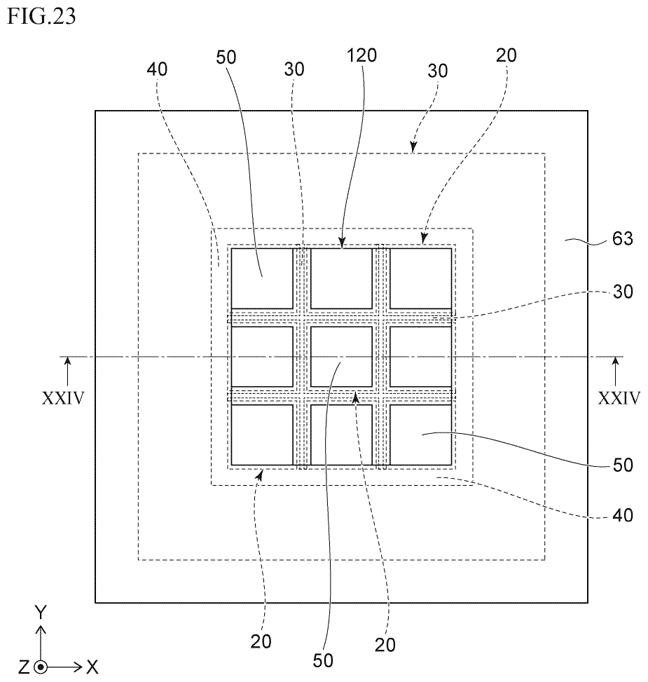

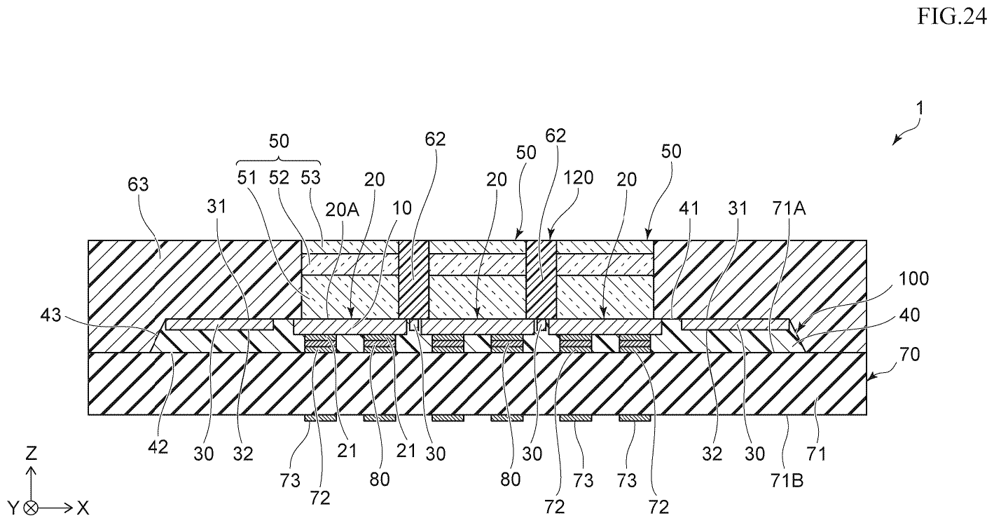

As illustrated in FIG. 23, the semiconductor portion 30 may be further provided between the plurality of semiconductor light-emitting units 20 in a plan view. FIG. 24 is a schematic cross-sectional view taken along line XXIV-XXIV in FIG. 23. The semiconductor portion 30 between the plurality of semiconductor light-emitting units 20 is located below the second resin member 62. The upper surface of the semiconductor portion 30 between the plurality of semiconductor light-emitting units 20 is covered by the second resin member 62.

When the semiconductor portion 30 is further located between the plurality of semiconductor light-emitting units 20, the area of the first resin surface 41 of the first resin member 40 can be further reduced, and the light absorption in the light-emitting device can be further reduced.

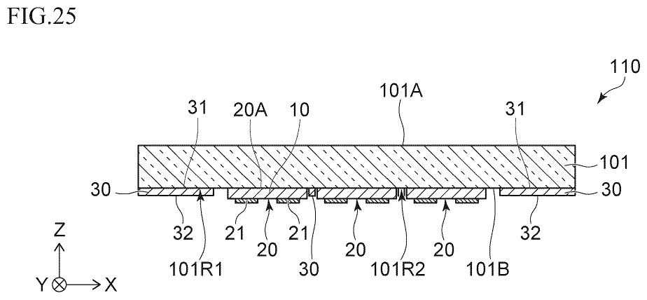

The method for manufacturing the light-emitting device illustrated in FIGS. 23 and 24 includes a step of providing the first structure 110 illustrated in FIG. 25. In the step of providing of the first structure 110 illustrated in FIG. 25, the semiconductor portion 30 is disposed in the outer peripheral region 101R1 and the inter-semiconductor light-emitting unit region 101R2 on the second surface 101B of the substrate 101. For example, when the semiconductor layer formed on the second surface 101B of the substrate 101 is divided into a plurality of semiconductor layers to be the plurality of semiconductor structures 10 and a semiconductor layer to be the semiconductor portion 30 by etching, a semiconductor layer to be the semiconductor portion 30 is left in the inter-semiconductor light-emitting unit region 101R2.

Embodiments of the present disclosure have been described above with reference to specific examples. However, the present invention is not limited to these specific examples. All aspects that can be practiced by a person skilled in the art modifying the design as appropriate based on the above-described embodiments of the present disclosure are also included in the scope of the present invention, as long as they encompass the spirit of the present invention. In addition, a person skilled in the art could conceive of various modifications and alterations within the scope of the described embodiments, and those modifications and alterations will also fall within the scope of the present invention.

What is claimed is:

1. A method for manufacturing a light-emitting device, the method comprising:
providing a first structure comprising:
a substrate having a first surface, and a second surface located opposite to the first surface,
a plurality of semiconductor light-emitting units disposed on the second surface of the substrate, and
a semiconductor portion disposed on the second surface in a region in which the plurality of semiconductor light-emitting units are not disposed, the semiconductor portion being configured to emit no light;
disposing the first structure on a support member such that the second surface faces the support member;
disposing a first resin member between a portion of the first structure and a portion of the support member; and
after the disposing of the first resin member, separating the substrate from the plurality of semiconductor light-emitting units and the semiconductor portion by irradiating laser light from a first surface side of the substrate toward the plurality of semiconductor light-emitting units and the semiconductor portion.

2. The method for manufacturing a light-emitting device, according to claim 1, wherein:
in the providing of the first structure:
the region of the second surface of the substrate in which the plurality of semiconductor light-emitting units are not disposed comprises an outer peripheral region surrounding the plurality of semiconductor light-emitting units, and an inter-semiconductor light-emitting unit region between the plurality of semiconductor light-emitting units, in a plan view,
a width of the outer peripheral region is greater than a width of the inter-semiconductor light-emitting unit region, and
the semiconductor portion is disposed in the outer peripheral region.

3. The method for manufacturing a light-emitting device, according to claim 2, wherein:
in the providing of the first structure, the semiconductor portion is further disposed in the inter-semiconductor light-emitting unit region.

4. The method for manufacturing a light-emitting device, according to claim 2, further comprising:
cutting the semiconductor portion and the first resin member in a position of the semiconductor portion after the separating of the substrate.

5. The method for manufacturing a light-emitting device, according to claim 4, wherein:
in the providing of the first structure, a thickness of the semiconductor portion is less than a thickness of each of the semiconductor light-emitting units.

6. The method for manufacturing a light-emitting device, according to claim 1, wherein:
in the providing of the first structure, the first structure comprises a metal layer disposed on the semiconductor portion; and
the semiconductor portion is located between the metal layer and the second surface.

7. The method for manufacturing a light-emitting device, according to claim 1, wherein:
the disposing of the first resin member comprises:
disposing the first structure and the support member in a mold;
supplying a resin material into the mold in a state in which the first surface of the substrate is covered by a covering member;
curing the resin material supplied into the mold; and
after the curing of the resin material, removing the covering member.

8. The method for manufacturing a light-emitting device, according to claim 1, further comprising:
after the separating of the substrate, disposing a second structure on the plurality of semiconductor light-emitting units, wherein:
the second structure comprises a plurality of light-transmissive members, and a second resin member disposed between the plurality of light-transmissive members.

9. The method for manufacturing a light-emitting device, according to claim 8, wherein:
the disposing of the second structure comprises:
disposing the plurality of light-transmissive members such that one of the light-transmissive members overlaps a corresponding one of the semiconductor light-emitting units in a plan view; and
disposing the second resin member between the plurality of light-transmissive members.

10. A light-emitting device comprising:
a plurality of semiconductor light-emitting units each having a light-emitting surface;
a first resin member having a first resin surface and disposed between the plurality of semiconductor light-emitting units such that the light-emitting surface is exposed on the first resin surface; and
a semiconductor portion having a lower surface and an upper surface, the lower surface being covered by the first resin member, the upper surface being exposed on the first resin surface, and the semiconductor portion being configured to emit no light, wherein:
a light reflectance of the first resin member in contact with the lower surface of the semiconductor portion is higher than a light reflectance of the first resin surface.

11. The light-emitting device according to claim 10, wherein:
the semiconductor portion surrounds the plurality of semiconductor light-emitting units in a plan view; and
a width of the semiconductor portion is greater than a distance between the plurality of semiconductor light-emitting units in a plan view.

12. The light-emitting device according to claim 10, wherein:
the semiconductor portion is further located between the plurality of semiconductor light-emitting units in a plan view.

13. The light-emitting device according to claim 10, wherein:
a thickness of the semiconductor portion is less than a thickness of each of the plurality of semiconductor light-emitting units.

14. The light-emitting device according to claim 10, further comprising:
a metal layer located on a lower surface side of the semiconductor portion.

15. The light-emitting device according to claim 10, further comprising:
a second structure disposed on the plurality of semiconductor light-emitting units, wherein:
the second structure comprises a plurality of light-transmissive members, and a second resin member disposed between the plurality of light-transmissive members.

16. The light-emitting device according to claim 10, further comprising:
a support member supporting the plurality of semiconductor light-emitting units, the semiconductor portion, and the first resin member, wherein:
a surface of each of the semiconductor light-emitting units located opposite to the light-emitting surface and the lower surface of the semiconductor portion face the support member.
